(19) United States
(12) Patent Application Publication
(10) Pub. No.: US 2025/0380613 A1
(43) Pub. Date: Dec. 11, 2025

(54) MONITORING A STATE OF A CONTRACTING MEMBER

(71) Applicant: Toyota Motor Engineering & Manufacturing North America, Inc., Plano, TX (US)

(72) Inventors: Daniel I. Williams, Ormond Beach, FL (US); Yufei Zhu, Ypsilanti, MI (US); William P. Dix, Highland Park, MI (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/738,516

(22) Filed: Jun. 10, 2024

(51) Int. Cl. H10N 30/80; B60N 2/90; G06F 3/01; H10N 30/20; H10N 30/857

(52) U.S. Cl. CPC H10N 30/802; B60N 2/976; G06F 3/016; H10N 30/204; H10N 30/857

(57) ABSTRACT

A supply of energy to a contracting member can be controlled based on a pulse width modulated (PWM) signal. A state of the contracting member can be controlled. An interruption in the controlling of the state of the contracting member can be caused when the PWM signal is high. An electrical characteristic of the contracting member can be measured within the interruption before the PWM signal switches to low.

### FIELD

The subject matter described herein relates in general to actuators and, more particularly, to contracting member-based actuators.

### BACKGROUND

Some motor vehicles have actuators in one or more portions of a vehicle seat. These actuators can provide a haptic effect to a seat occupant. Such an effect can provide support and/or comfort to a seat occupant.

### SUMMARY

In one respect, the present disclosure is directed to a method. The method includes controlling a supply of electrical energy to a contracting member based on a pulse width modulated (PWM) signal. The method includes controlling a state of the contracting member. The method includes causing an interruption of the controlling the state of the contracting member when the PWM signal is high. The method includes measuring an electrical characteristic of the contracting member within the interruption before the PWM signal switches to low.

In another respect, the present disclosure is directed to a system. The system includes a contracting member and an energy source operatively connected to supply electrical energy to the contracting member. The system includes one or more processors operatively connected to the contracting member and to the energy source. The one or more processors can be programmed to control a supply of electrical energy from the energy source to the contracting member based on a pulse width modulated (PWM) signal. The one or more processors can be programmed to cause an interruption of the controlling the state of the contracting member when the PWM signal is high. The one or more processors can be programmed to measure an electrical characteristic of the contracting member within the interruption before the PWM signal switches to low.

### BRIEF DESCRIPTION OF THE DRAWINGS

FIG. 1 shows an example of a system for monitoring and/or controlling a state of a contracting member.

FIG. 2 is an example of an operational scheme that uses an interrupt service routine with respect to measuring an electrical characteristic of a contracting member.

FIG. 3 is an example of a graph, showing an example of a relationship between a counting of a timer and a pulse width modulated signal over time.

FIG. 4A is a first example of an operational scheme for triggering an interrupt service routine and an action to be performed within the interruption.

FIG. 4B is an example of a logic table for the operational scheme of FIG. 4A.

FIG. 5A is a second example of an operational scheme for triggering an interrupt service routine and an action to be performed within the interruption.

FIG. 5B is an example of a logic table for the operational scheme of FIG. 5A.

FIG. 6 is an example of a graph of current versus time, showing a cooling and heating cycle for a contracting member.

FIG. 7A is an example of a first portion of an operational scheme for cycling a contracting member between cooling and heating cycles.

FIG. 7B is an example of a second portion of the operational scheme for cycling the contracting member between cooling and heating cycles.

FIG. 8 is an example of a two buffer system for cycling the contracting member between cooling and heating cycles.

FIG. 9 is an example of a method of monitoring and/or controlling a state of a contracting member.

### DETAILED DESCRIPTION

Some actuators used in vehicles use shape memory alloys or other contracting members for actuation. Contracting members can be prone to overstress, overheating, and/or overcooling, which can lead to a reduced life of the contracting members, reduced effectiveness of the actuators, and excessive power consumption. Accordingly, arrangements described herein are directed to monitoring the state of a contracting member, such as a shape memory material member.

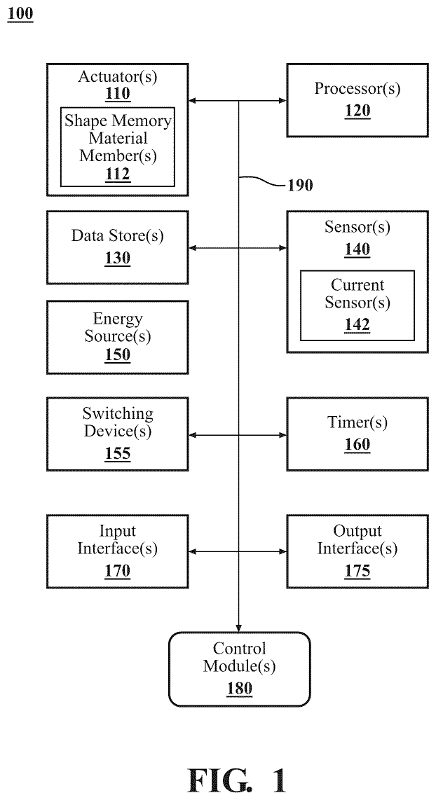

Detailed embodiments are disclosed herein; however, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-9, but the embodiments are not limited to the illustrated structure or application.

FIG. 1 shows an example of a system 100 for monitoring and/or controlling a state of a shape memory material member. The system 100 can include an actuator 110, one or more processors 120, one or more data stores 130, one or more sensors 140, one or more energy sources 150, one or more switching devices 155, one or more timers 160, one or more input interfaces 170, one or more output interfaces 175, and/or one or more control modules 180.

The various elements of the system 100 can be communicatively linked to one another or one or more other elements through one or more communication networks 190. As used herein, the term “communicatively linked” can include direct or indirect connections through a communication channel, bus, pathway or another component or system. A “communication network” means one or more components designed to transmit and/or receive information from one source to another. The data store(s) 130 and/or one or more other elements of the system 100 can include and/or execute suitable communication software, which enables the various elements to communicate with each other through the communication network and perform the functions disclosed herein.

The one or more communication networks 190 can be implemented as, or include, without limitation, a wide area network (WAN), a local area network (LAN), the Public Switched Telephone Network (PSTN), a wireless network, a mobile network, a Virtual Private Network (VPN), the Internet, a hardwired communication bus, and/or one or more intranets. The communication network 190 further can be implemented as or include one or more wireless networks, whether short range (e.g., a local wireless network built using a Bluetooth or one of the IEEE 802 wireless communication protocols, e.g., 802.11a/b/g/i, 802.15, 802.16, 802.20, Wi-Fi Protected Access (WPA), or WPA2) or long range (e.g., a mobile, cellular, and/or satellite-based wireless network; GSM, TDMA, CDMA, WCDMA networks or the like). The communication network 190 can include wired communication links and/or wireless communication links. The communication network 190 can include any combination of the above networks and/or other types of networks.

Some of the potential elements of the system 100 will be described in turn below. In some arrangements, the system 100 can include an actuator 110. The actuator 110 is represented generally as there are various suitable actuators that can work with arrangements herein. In some arrangements, the actuator 110, when activated, can be configured to morph into an activated configuration in which a dimension (e.g., a height) of the actuator 110 increases.

In some arrangements, the actuator 110 include one or more contracting members. The contracting member(s) can be any structure that, when activated, is configured to shrink in length. In some arrangements, the actuator 110 can be just the contracting member(s).

In one or more arrangements, the contracting member(s) can include shape memory material members 112, which can include one or more active materials, memory materials, shape memory alloys, and shape memory polymers. Thus, the actuator 110 be a shape memory material based actuator. The contracting member(s) are shown as being a part of the actuator(s) 110, it will be appreciated that, in some arrangements, the contracting member(s) can be actuator(s) 110. Further, it will be appreciated that, in some arrangements, the system 100 may not have the one or more actuator(s) 110; instead, the system 100 can include one or more contracting members.

When an activation input is provided to the shape memory material member(s) 112, the shape memory material member(s) 112 can contract, thereby causing the actuator to morph into an activated configuration in which a dimension of the actuator 110 increases (e.g., a height of the actuator increases). In some arrangements, the contracting member can be in the form of a wire, such as a shape memory alloy wire.

The phrase “shape memory material” includes materials that changes shape when an activation input is provided to the shape memory material and, when the activation input is discontinued, the material substantially returns to its original shape. Examples of shape memory materials include shape memory alloys (SMA) and shape memory polymers (SMP).

In one or more arrangements, the shape memory material members can be shape memory material wires. As an example, the shape memory material members can be shape memory alloy wires. Thus, when an activation input (e.g., heat, electrical energy, energy) is provided to the shape memory alloy wire(s), the wire(s) can contract. Shape memory alloy wire(s) can be heated in any suitable manner, now known or later developed. For instance, shape memory alloy wire(s) can be heated by the Joule effect by passing electrical current through the wires. In some instances, arrangements can provide for cooling of the shape memory alloy wire(s), if desired, to facilitate the return of the wire(s) to a non-activated configuration. Of course, it will be appreciated that the activation input can be provided to the shape memory alloy wire(s) in other ways. For example, heated air can be blown on the shape memory alloy wire(s).

The wire(s) can have any suitable characteristics. For instance, the wire(s) can be high temperature wires with austenite finish temperatures from about 80 degrees Celsius to about 110 degrees Celsius. The wire(s) can have any suitable diameter. For instance, the wire(s) can be from about 0.2 millimeters (mm) to about 0.7 mm, from about 0.3 mm to about 0.5 mm, or from about 0.375 millimeters to about 0.5 millimeters in diameter. In some arrangements, the wire(s) can have a stiffness of up to about 70 gigapascals. The pulling force of SMA wire(s) can be from about 150 MPA to about 400 MPa. The wire(s) can be configured to provide an initial moment of from about 300 to about 600 N·mm, or greater than about 500 N·mm, where the unit of newton millimeter (N·mm) is a unit of torque (also called moment) in the SI system. One newton meter is equal to the torque resulting from a force of one newton applied perpendicularly to the end of a moment arm that is one meter long. In various aspects, the wire(s) can be configured to transform in phase, causing the shape memory material members to be moved from non-activated position to an activated position in about 3 seconds or less, about 2 seconds or less, about 1 second or less, or about 0.5 second or less.

The wire(s) can be made of any suitable shape memory material, now known or later developed. Different materials can be used to achieve various balances, characteristics, properties, and/or qualities. As an example, an SMA wire can include nickel-titanium (Ni—Ti, or nitinol). One example of a nickel-titanium shape memory alloy is FLEXINOL, which is available from Dynaolloy, Inc., Irvine, California. As a further example, the SMA wires can be made of Cu—Al—Ni, Fe—Mn—Si, or Cu—Zn—Al.

The SMA wire can be configured to increase or decrease in length upon changing phase, for example, by being heated to a phase transition temperature T_{SMA}. Utilization of the intrinsic property of SMA wires can be accomplished by using heat, for example, via the passing of an electric current through the SMA wire in order provide heat generated by electrical resistance, in order to change a phase or crystal structure transformation (i.e., twinned martensite, detwinned martensite, and austenite) resulting in a lengthening or shortening the SMA wire. In some implementations, during the phase change, the SMA wire can experience a decrease in length of from about 2 to about 8 percent, or from about 3 percent to about 6 percent, and in certain aspects, about 3.5 percent, when heated from a temperature less than the T_{SMA} to a temperature greater than the T_{SMA}.

The SMA wire can have a critical temperature. Once the critical temperature is reached, the SMA wire cannot produce any more force. Thus, if the SMA wire is heated above the critical temperature, it cannot produce any more force. This inherent property of the SMA wire can be leveraged according to arrangements described herein.

Other active materials may be used in connection with the arrangements described herein. For example, other shape memory materials may be employed. Shape memory materials, a class of active materials, also sometimes referred to as smart materials, include materials or compositions that have the ability to remember their original shape, which can subsequently be recalled by applying an external stimulus, such as an activation signal.

While the shape memory material members are described, in some implementations, as being wires, it will be understood that the shape memory material members are not limited to being wires. Indeed, it is envisioned that suitable shape memory materials may be employed in a variety of other forms, such as sheets, plates, panels, strips, cables, tubes, or combinations thereof. In some arrangements, the shape memory material members may include an insulating coating.

In some arrangements, the actuator 110 can include a single shape memory material member 112. In some instances, one or more portions of the shape memory material member 112 can extend external to overall envelope of the actuator 110.

The shape memory material member 112 can have any suitable routing with respect to the actuator 110. For instance, in some arrangements, the shape memory material member 112 can extend substantially linearly within the actuator 110. In other arrangements, the shape memory material member 112 can extend in a non-linear manner, such as in a serpentine or a zig-zag arrangement. The shape memory material member 112 can exit the actuator 110 and can extend external to the actuator 110.

The shape memory material member 112 can be activated and/or deactivated using any suitable form of energy and/or from any suitable source. For example, in some arrangements, the of the shape memory material member 112 can be operatively connected to a power source (e.g., the energy source(s) 150).

However, it will be appreciated that arrangements described herein are not limited to activating and/or deactivating the shape memory material member 112 based on electrical energy. Indeed, as an example, the shape memory material member 112 can be activated and/or by supplying hot air, such as from a heater or some other heat source, to the shape memory material member 112. The heater can be operatively positioned with respect to the shape memory material member 112.

There are various actuators that are suitable for use in connection with arrangements described herein. Non-limiting examples of suitable actuators are described in U.S. Pat. Nos. 10,960,793; 11,370,330; 11,285,844; 11,091,060; 11,752,901; 11,897,379; 11,592,010; 11,841,008; 11,592,037; 11,927,206; 11.248.592; 11,542,925; 11,732,735; 11,460,009; 11,536,255; 11,795,924; 11,624,376; 11,472,325; 10,532,672; and 10,933,974; U.S. Patent Publication Nos. 2023/0191953; 2023/0136197; 2024/0060480; 2023/0179122; and 2023/0193929, and U.S. patent application Ser. Nos. 18/329,217; 18/399,026; 18/453,395; 18/452,343; 18/452,376; 18/452,734; 17/729,522; 18/172,637; and Ser. No. 18/433,896, all of which are incorporated herein by reference in their entireties.

As noted above, the system 100 can include one or more processors 120. “Processor” means any component or group of components that are configured to execute any of the processes described herein or any form of instructions to carry out such processes or cause such processes to be performed. The processor(s) 120 may be implemented with one or more general-purpose and/or one or more special-purpose processors. Examples of suitable processors include microprocessors, microcontrollers, DSP processors, and other circuitry that can execute software. Further examples of suitable processors include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, and a controller. The processor(s) 120 can include at least one hardware circuit (e.g., an integrated circuit) configured to carry out instructions contained in program code. In arrangements in which there is a plurality of processors 120, such processors can work independently from each other or one or more processors can work in combination with each other.

The system 100 can include one or more data stores 130 for storing one or more types of data. The data store(s) 130 can include volatile and/or non-volatile memory. Examples of suitable data stores 130 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The data store(s) 130 can be a component of the processor(s) 120, or the data store(s) 130 can be operatively connected to the processor(s) 120 for use thereby. The term “operatively connected,” as used throughout this description, can include direct or indirect connections, including connections without direct physical contact.

In some arrangements, the data store(s) 130 can store information or data about the contracting member(s) and/or the actuator(s) 110, such as any of those used in connection with arrangements described herein. As an example, such data can include material properties and characteristics of the contracting member(s). As another example, such data can include stress-strain curves for the contracting member(s). In some instances, the stress-strain curves can show the performance of the respective shape memory material member at a plurality of different temperatures.

In some arrangements, the data store(s) 130 can store one or more actuation profiles. The actuation profile(s) can include instructions for activating the actuator(s) 110 in a specified manner. The actuation profile(s) can include activation patterns, activation sequences, activation zones, activation regions, activation times, activation of individual actuators or groups of actuators, etc. The actuation profile(s) can be created by an end user or some other entity (e.g., a manufacturer or provider). In some instances, one or more actuation profile(s) can be received from a remote source.

The system 100 can include one or more sensors 140. “Sensor” means any device, component and/or system that can detect, determine, assess, monitor, measure, quantify, acquire, and/or sense something. The one or more sensors can detect, determine, assess, monitor, measure, quantify, acquire, and/or sense in real-time. As used herein, the term “real-time” means a level of processing responsiveness that a user or system senses as sufficiently immediate for a particular process or determination to be made, or that enables the processor to keep up with some external process.

In arrangements in which the system 100 includes a plurality of sensors 140, the sensors can work independently from each other. Alternatively, two or more of the sensors can work in combination with each other. In such case, the two or more sensors can form a sensor network. The sensor(s) 140 can be operatively connected to the processor(s) 120, the data store(s) 130, and/or other elements of the system 100 (including any of the elements shown in FIG. 1).

The sensor(s) 140 can include any suitable type of sensor, now known or later developed, that can acquire information or data about the actuator 110, the contracting member(s) (e.g., the shape memory material member(s) 112), or any other portion or component of the system 100 of FIG. 1.

In one or more arrangements, the sensor(s) 140 can be configured to acquire data about one or more electrical characteristics of the contracting member(s), including current, resistance, voltage, other electrical characteristics, or any combination thereof. In one or more arrangements, the sensor(s) 140 can include one or more multimeters. The multimeter(s) can be operatively connected to acquire data about one or more electrical characteristics of the contracting member(s). In some arrangements, the sensor(s) 140 can be one or more ohmmeters, one or more voltmeters, and/or one or more current sensors 142. The current sensor(s) 142 can include one or more ammeters or any device, system, structure, or component, now known or later developed, that can directly or indirectly measure electrical current.

As noted above, the system 100 can include one or more energy sources 150. The energy source(s) 150 can be any energy source capable of and/or configured to energize the contracting member of the actuator 110. For example, the energy source(s) 150 can include one or more power sources, one or more batteries, one or more fuel cells, one or more generators, one or more alternators, one or more solar cells, one or more heat sources, and combinations thereof. The energy source(s) 150 can be any suitable source of energy, such as electrical energy. The energy source(s) 150 can be operatively connected to the contracting member(s) (e.g., the shape memory material member(s) 112) of the actuator 110. The energy source(s) 150 can be configured to supply electrical energy, such as to the contracting member(s).

The system 100 can include one or more switching devices 155. In some arrangements, the switching device(s) 155 can be operatively positioned between the energy source(s) 150 and the contracting member(s). The switching device(s) 155 can be controlled, such as by the one or more processor(s) 120, to control the supply of energy from the energy source(s) 150 to the contracting member(s). In some arrangements, the processor(s) 120 can be configured to control the switching device(s) 155 based on a pulse width modulated (PWM) signal. The switching device(s) 155 can be any suitable type of switching device, now known or later developed. In some instances, the switching device(s) 155 can be mechanical, electrical, or electromechanical. Non-limiting examples of the switching device(s) 155 include one or more optocouplers, one or more metal-oxide-semiconductor field-effect transistors (MOSFETs), one or more relays, one or more switches, or any combination thereof.

The system 100 can include one or more timers 160. The timer(s) 160 can be any suitable timer, now known or later developed. The timer(s) 160 can be configured to count up or down from an event, starting point, command, input, etc. In some arrangements, the timer(s) 160 can be part of the processor(s) 120. The timer(s) 160 can be used in the generation of the PWM signal. The timer(s) 160 can be used in the generation of an interrupt service routine. In this way, the PWM signal and the interrupt service routing can be generated from the same source.

The system 100 can include one or more input interfaces 170. An “input interface” includes any device, component, system, element or arrangement or groups thereof that enable information/data to be entered into a machine. The input interface(s) 170 can receive an input from a person or entity. Any suitable input interface 170 can be used, including, for example, a keypad, gesture recognition interface, voice recognition interface, display, touch screen, multi-touch screen, button, joystick, mouse, trackball, microphone and/or combinations thereof.

The system 100 can include one or more output interfaces 175. An “output interface” includes any device, component, system, element or arrangement or groups thereof that enable information/data to be presented to a person or entity. The output interface(s) 175 can include a display. Alternatively or in addition, the output interface(s) 175 may include an earphone and/or speaker. Some components of the system 100 may serve as both a component of the input interface(s) 170 and a component of the output interface(s) 175.

The system 100 can include one or more modules, at least some of which will be described herein. The modules can be implemented as computer readable program code that, when executed by a processor, implements one or more of the various processes described herein. One or more of the modules can be a component of the processor(s) 120, or one or more of the modules can be executed on and/or distributed among other processing systems to which the processor(s) 120 is operatively connected. The modules can include instructions (e.g., program logic) executable by one or more processor(s) 120. Alternatively or in addition, one or more data stores 130 may contain such instructions. In some arrangements, the module(s) can be located remote from the other elements of the system 100.

In one or more arrangements, the modules described herein can include artificial or computational intelligence elements, e.g., neural network, fuzzy logic or other machine learning algorithms. Further, in one or more arrangements, the modules can be distributed among a plurality of modules. In one or more arrangements, two or more of the modules described herein can be combined into a single module.

The system 100 can include one or more control modules 180. The control module(s) 180 can include profiles and logic for controlling the actuator 110 and/or other elements of the system 100. The control module(s) 180 can use profiles, parameters, logic, or settings loaded into the control module(s) 180 and/or stored in the data store(s) 130. In some arrangements, the control module(s) 180 can be located remotely from the other elements of the system 100, such as on a remote server, a cloud-based server, or an edge server.

The control module(s) 180 can be configured to cause one or more of the actuators 110 to be activated or deactivated. As used herein, “cause” or “causing” means to make, force, compel, direct, command, instruct, and/or enable an event or action to occur or at least be in a state where such event or action may occur, either in a direct or indirect manner. For instance, the control module(s) 180 can cause the actuator 110 to be selectively activated or deactivated in any suitable manner. For instance, when the actuator 110 includes a shape memory material member 112, the shape memory material member 112 can be heated by the Joule effect by passing electrical current through the shape memory material member 112. To that end, the control module(s) 180 can be configured to selectively permit, restrict, adjust, alter, and/or prevent the flow of electrical energy from the energy source(s) 150 to the shape memory material member 112 of the actuator 110. The control module(s) 180 can be configured to send control signals or commands over a communication network 190 to one or more elements of the system 100.

The control module(s) 180 can be configured to cause the actuator(s) 110 to be activated or deactivated based on various events, conditions, inputs, or other factors. For instance, the control module(s) 180 can be configured to cause the actuator(s) 110 to be activated or deactivated based on a user input. A user can provide an input on the input interface(s) 170.

In some instances, the control module(s) 180 can be configured to adjust the degree of activation of the actuator(s) 110. For instance, the control module(s) 180 can be configured to cause the actuator(s) 110 to be in an activated configuration that corresponds to its full activated position (e.g., extended to its maximum height). The control module(s) 180 can be configured to activate the actuator(s) 110 to one or more activated configurations between the non-activated configuration and the full activated configuration, such as an extended position but less than its maximum height. The control module(s) 180 can be configured to maintain the activated configuration of the actuator(s) 110. The control module(s) 180 can be configured to adjust the activated configuration of the actuator(s) 110.

The control module(s) 180 can be configured to generate pulse width modulated (PWM) signals or to cause PWM signals to be generated. The control module(s) 180 can do so in any suitable manner, now known or later developed. The control module(s) 180 can be configured to set and/or adjust one or more characteristics of the PWM signal, including duty cycle and/or frequency. The PWM signal can be generated based on the timer(s) 160.

The control module(s) 180 can be configured to control a supply of energy from the energy source(s) 150 to the contracting member(s) based on the PWM signals. It should be noted that, when there is a plurality of contracting member(s) (e.g., in a single actuator 110 or in a plurality of actuators 110), the control module(s) 180 can control the supply of energy to each individual contracting member, to all contracting members as a group, or to any subset of the plurality of contracting members.

As noted above, the switching device(s) 155 can be operatively positioned between the energy source(s) 150 and the contracting member(s). The energy source(s) 150 can be constantly supplying energy, but the energy may or may not reach the contracting member(s) based on the state of the switching device(s) 155. The control module(s) 180 can control the switching device(s) 155 based on the PWM signal. For instance, when the PWM signal is low or off, the control module(s) 180 can be configured to open the switching device(s) 155. As a result, the flow of energy from the energy source(s) 150 to the contracting member(s) is stopped due to an open circuit. When the PWM signal is on, the control module(s) 180 can be configured to close the switching device(s) 155. As a result, the circuit between the energy source(s) 150 and the contracting member(s) is closed, thereby allowing the flow of energy from the energy source(s) 150 to the contracting member(s). When the PWM signal is low, the control module(s) 180 can be configured to cause the flow of energy from the energy source(s) 150 to the contracting member(s) to be at a low or reduced level. When the PWM signal is high, the control module(s) 180 can be configured to cause the flow of energy from the energy source(s) 150 to the contracting member(s) to be at a high or increased level.

The control module(s) 180 can control the supply of electrical energy from the energy source(s) 150 to the contracting member(s) to affect a state of the contracting member(s). For instance, in a heating cycle, the control module(s) 180 can set the PWM signal at a duty cycle that causes a temperature of the contracting member(s) to increase. As the contracting member heats up, the contracting member can contract as noted above. In a cooling cycle, the control module(s) 180 can set the PWM signal at a duty cycle that does not cause a temperature of the contracting member to increase. Thus, the contracting member can cool and eventually will relax, possibly relaxing to a non-activated state.

The control module(s) 180 and/or the processor(s) 120 can be configured to monitor and/or control a state of the contracting member. Such monitoring and/or controlling can be performed by the processor(s) 120 initiating or executing a main code (e.g., executable operations) for monitoring and/or controlling the state of the contracting member.

According to arrangements herein, the control module(s) 180 can be configured to cause an interruption of the controlling and/or monitoring of the state of the contracting member when the PWM signal is high. Generally, the “interruption” includes stopping one action with another action. The interruption is temporary in nature, and, once the action associated with the interruption is completed, the action that was interrupted can resume at the point of the interruption. The interruption can create an opportunity for some action or executable operation to be performed within the interruption.

The interruption of the controlling and/or monitoring of the state of the contracting member when the PWM signal is high can be caused in any suitable manner, now known or later developed. In one or more arrangements, the interruption can be performed using an interrupt service routine (ISR). The ISR can be a block of code that takes priority over other code. The ISR can be a relatively short block of code relative to the main code. Also, the ISR can be for a duration that is less than the time when the PWM signal is on. The ISR can cause a main code (e.g., the executable operations for monitoring and/or controlling the state of a contracting member) to be stopped and the code associated with the ISR can be performed.

The code associated with the ISR can perform any action. For example, the action can include taking a measurement of one or more electrical characteristics of the contracting member (e.g., current) within the interruption while the PWM signal is high and before it is switched to low or off. Other examples include saving a measurement of an electrical characteristic or other characteristic or setting a flag to take a measurement of an electrical characteristic or other characteristic.

The control module(s) 180 can be configured to cause a measurement of one or more electrical characteristics of the contracting member(s). In view of the supply of energy to the contracting members based on a PWM signal, the control module(s) 180 can be configured to cause a measurement of the electrical characteristic of the contracting member within the interruption before the PWM signal switches to low or off. The control module(s) 180 can cause one or more of the sensor(s) 140 to take such a measurement. The timing of the measurement will be described herein.

The measured electrical characteristic can be saved, such as to the data store(s) 130. The measured electrical characteristic can be used in the monitoring and/or control of the contracting member. Arrangements described herein can enable a user to set a frequency of the PWM signal to set a sampling rate.

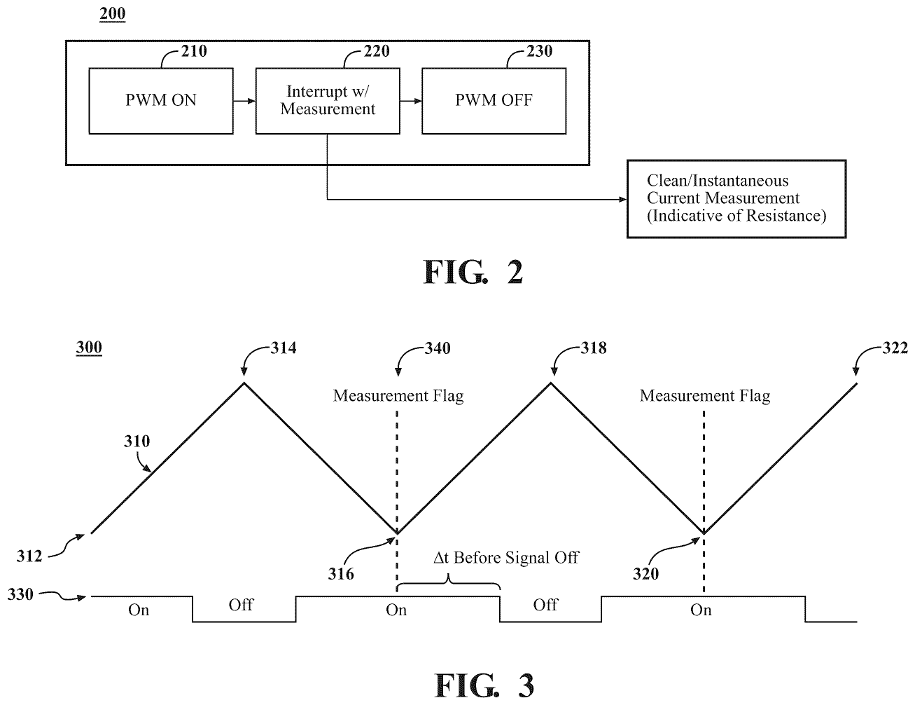

FIG. 2 shows an example of an operational scheme 200 of the control module(s) 180. More particularly, FIG. 2 shows a use of an ISR with respect to measuring electrical characteristic(s) of the contracting member(s). At block 210, the PWM signal can be on (or high). At block 220, while it is on (or high), an interruption can be effectuated by an ISR and an action (e.g., a measurement of the electrical characteristic(s) of the contracting member(s)) can be taken within the interruption before the PWM signal switches to low or off. At block 230, the PWM signal can be turned off (or low). In some arrangements, the measurement can be made at the moment the PWM signal is turned off but while the PWM signal is still on (or high). In other arrangements, the measurement can be made at any time before the PWM signal is turned off (or low). It will be appreciated that, according to this scheme, a clean and instantaneous measurement of current can be obtained. The measurement can be indicative of resistance.

The timer(s) 160 can be used in connection with the PWM signal. The timer(s) 160 can be used in the generation of the PWM signal as well as the ISR. The timer(s) 160 can be configured to count up from zero or other baseline number to a maximum number or other comparison number or value. Once the maximum number is reached or other comparison number or value, then timer(s) 160 can count back down to zero or other baseline number, or the timer(s) 160 can reset to zero or other baseline number. The timer(s) 160 can count at a substantially constant rate.

FIG. 3 is an example of a graph 300, showing the interplay between the counting of the timer(s) 160 and the PWM signal over time. The timer counting is represented by triangle wave 310, and the PWM signal 330 is represented by rectangular wave.

In this particular example, the timer(s) 160 can begin at point 312, counting up from zero or from some baseline number. From there, the timer(s) 160 can count up to a maximum number. The timer(s) 160 can be configured to count at a constant rate. The timer(s) 160 can reach the maximum number at point 314. From there, the timer(s) 160 can count down back down to zero (or other baseline number), as shown at point 316. The process can be repeated with the timer counting up to point 318, down to point 320, and back up to point 322. It will be appreciated that any maximum number can be set and the maximum number can be varied as appropriate.

The PWM signal 330 can be tied to the counting of the timer(s) 160. At point 312 of the counting, the PWM signal is on. When the maximum number is reached at point 314, the PWM signal 330 will be off (or low). More particularly, point 314 can correspond to substantially the middle of the off (or low) portion of the PWM signal 330. The timer(s) 160 can count down to point 316, at which point the PWM signal 330 will be on (or high). More particularly, point 316 can correspond to substantially the middle of the on (or high) portion of the PWM signal 330.

A measurement flag 340 can be set at this point. There is a period of time Δt before the PWM signal 330 is turned off. The control module(s) 180 can be configured to measure or cause to measure the electrical characteristic(s) of the contracting member(s) within the period of time Δt.

The interruption and the measurement of the electrical characteristic(s) of the contracting member(s) can be triggered in any suitable manner. Non-limiting examples of such triggering will now be described.

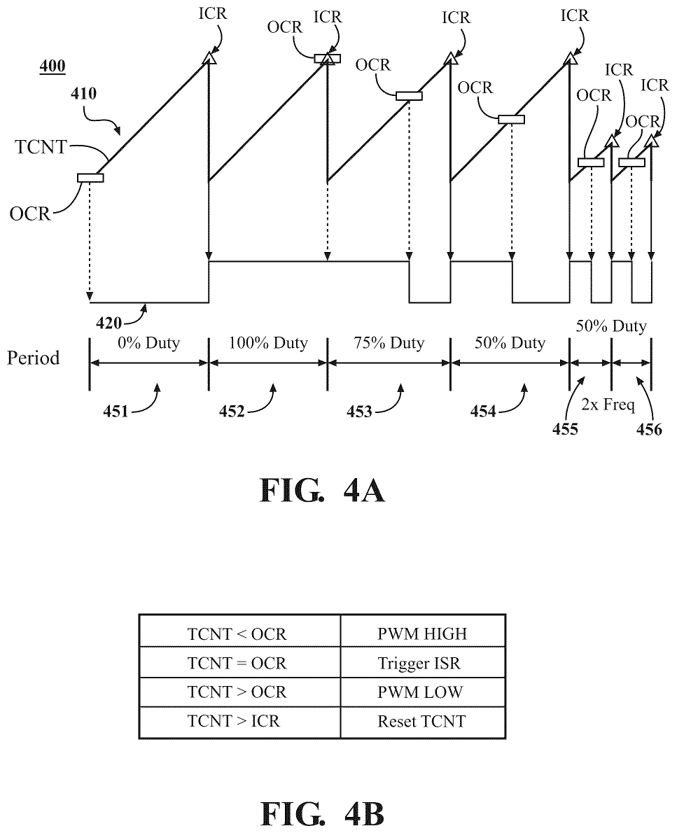

In one or more arrangements, the ISR and/or measurement can be triggered by comparing a timer counting value to one or more other values. One example of doing so is shown in connection with FIGS. 4A and 4B. FIG. 4A shows a graph 400 of a timer counter 410 and a PWM signal 420 over time. Also shown is the period of the PWM signal 420, which changes over time. There can be a timer counting value TCNT which corresponds to the counting by the timer(s) 160. There can be an output compare register value OCR. The output compare register value OCR can set the duty cycle. The output compare register value OCR can be set by a user or other entity. In this arrangement, the output compare register value OCR can be the value at which the ISR and the measurement will be triggered. There can be an input compare register value ICR. The input compare register value ICR can set the frequency of the PWM signal. The input compare register value ICR can correspond to a value at which point the timer counting value TCNT is reset. It should be noted that the output compare register value OCR and the input compare register value ICR can be changed, if necessary or desired, for each period of the PWM signal 420.

FIG. 4B shows a logic table for triggering the ISR and the measurement. When the timer counting value TCNT is less than the output compare register value OCR, the PWM signal 420 is high (or on if the PWM signal is off). When the timer counting value TCNT equals the output compare register value OCR, the ISR and the measurement can be triggered. When the timer counting value TCNT is greater than the output compare register value OCR, the PWM signal 420 can be switched to low. It will be appreciated that low can include off. When the timer counting value TCNT is greater than the input compare register value ICR, then timer counting value TCNT can be reset. It will be appreciated that, by adjusting the output compare register value OCR, both the duty cycle and the timing of when the interrupt occurs within the period can be controlled.

With the logic table of FIG. 4B in mind, the graph 400 in FIG. 4A will now be described. The various periods of the PWM signal 420 will be reviewed in turn from left to right. In a first period 451, the duty cycle can be 0%, meaning the PWM signal 420 is low for the duration of the first period 451. The timer counter 410 can start at zero or other baseline value. The timer counter 410 (and the timer counting value TCNT) can increase from there. In the first period 451, the output compare register value OCR can be set to zero or the baseline counting value. Thus, as the timer(s) 160 begin counting, the timer counting value TCNT will exceed the output compare register value OCR, so the PWM signal 420 remains low. A measurement may or may not be made at the very beginning of the first period 451. The value of the timer counter 410 can be compared to the input compare register value ICR. When the value of the timer counter 410 is greater than (or equal to) the input compare register value ICR, the timer counter 410 can reset to zero or other baseline value.

The second period 452 can begin. In the second period 452, the output compare register value OCR can be set to maximum counter value and/or to the input compare register value ICR. Here, the output compare register value OCR can be equal to the input compare register value ICR. The timer(s) 160 can begin to count, and the timer counting value TCNT can increase. The PWM signal 420 can be high at all times during the second period 452 because the timer counting value TCNT is less than the output compare register OCR. Thus, the duty cycle can be 100% for the second period 452.

As the timer counting value TCNT increases, it will be less than the output compare register value OCR and the input compare register value ICR. When the timer counting value TCNT equals the output compare register value OCR, the ISR can be triggered and an associated action (e.g., the measurement of an electrical characteristic of the contracting member) can be performed within the interruption. When the timer counting value TCNT exceeds the input compare register value ICR, the timer counting value TCNT can be reset to zero. It will be appreciated that, during the second period 452, the duty cycle can be 100%, meaning that the PWM signal 420 is on for the entire period.

In a third period 453, the output compare register value OCR can be set to about 75% of the maximum counting value (or 75% of the ICR value). At the beginning of the third period 453, the PWM signal 420 can remain high because timer counting value TCNT did not exceed the output compare register value OCR. When the timer counting value TCNT equals the output compare register value OCR, the ISR can be triggered and an associated action (e.g., a measurement of an electrical characteristic of the contracting member) can be performed within the interruption. When the timer counting value TCNT exceeds the output compare register value OCR, the PWM signal 420 can be switched to low or off. It will be appreciated that the measurement is made while the PWM signal 420 is still high just before it is switched to low (or off). The timer counting value TCNT continues to increase. The PWM signal 420 can remain low because the timer counting value TCNT is greater than the output compare register value OCR. When the timer counting value TCNT exceeds the input compare register value ICR, the timer counting value TCNT can be reset to zero. In the third period 453, the duty cycle is 75% because the PWM signal 420 is on 75% of the time and off 25% of the time.

In a fourth period 454, the output compare register value OCR can be set to about 50% of the maximum counting value (or about 50% of the ICR value). The PWM signal 420 can switch to high (or on) because it is less than the output compare register value OCR. When the timer counting value TCNT equals the output compare register value OCR, the ISR can be triggered and associated action (e.g., a measurement of an electrical characteristic of the contracting member) can be taken within the interruption. When the timer counting value TCNT exceeds the output compare register value OCR the PWM signal 420 can be switched to low. It will be appreciated that the measurement is made while the PWM signal 420 is high just before it switches to low. The timer counting value TCNT can continue to increase. The PWM signal 420 can remain low because the timer counting value TCNT is greater than the output compare register value OCR. When the timer counting value TCNT exceeds the input compare register value ICR, the timer counting value TCNT can be reset to zero. In the fourth period 454, the duty cycle is 50% because the PWM signal 420 is on 50% of the time and off 50% of the time.

In a fifth period 455, the output compare register value OCR can be set to about 50% of the maximum counting value (or 50% of the ICR), which, in this example, is less than the maximum counting value (or ICR) in the preceding periods. At the beginning of the fifth period 455, the PWM signal 420 can switch to high because the timer counting value TCNT is less than the output compare register value OCR. When the timer counting value TCNT equals the output compare register value OCR, the ISR can be triggered and an associated action (e.g., a measurement of an electrical characteristic of the contracting member) can be performed within the interruption. When the timer counting value TCNT exceeds the output compare register value OCR, the PWM signal 420 can be switched to low. It will be appreciated that the measurement is made while the PWM signal 420 is still high just before it switches to low. The timer counting value TCNT can continue to increase. The PWM signal 420 can remain low because the timer counting value TCNT is greater than the output compare register value OCR. When the timer counting value TCNT exceeds the input compare register value ICR, the timer counting value TCNT can be reset to zero. In the fourth period 454, the duty cycle is 50% because the PWM signal 420 is on 50% of the time and off 50% of the time.

In a sixth period 456, the above description of the fifth period 455 applies. However, it is noted that the frequency of the PWM signal 420 has increased. More particularly, the frequency of PWM signal 420 in the fifth period 455 and the sixth period 456 is two times greater than the frequency of the PWM signal in the fourth period 454.

The measurements and the timing of the measurements can be stored in the data store(s) 130. The measurements can be provided as feedback to the control module(s) 180. Such feedback can be useful to monitoring and/or controlling the state of the contracting member(s).

In the example of FIGS. 4A-4B, there is a single value that triggers the ISR and causes the associated action (e.g., the measurement of the electrical characteristic of the contracting member) as well as setting the duty cycle. It is worth noting that this arrangement may have a small margin for error in the measurement. For the measurement to be meaningful, it should be made while the PWM signal is high. Accordingly, in some instances, measurements or information obtained in prior periods can be used to offset the time in which the measurement is made relative to the point at which the PWM signal 420 switches to low.

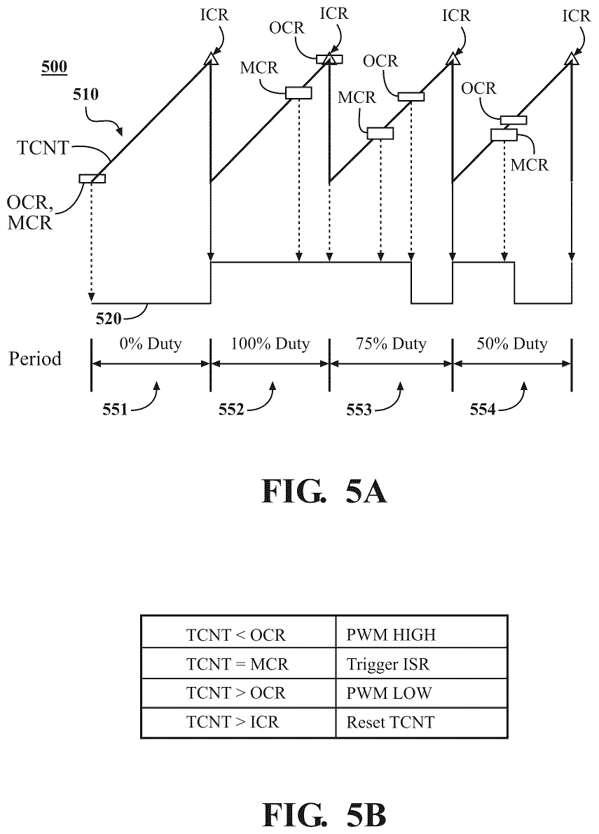

In one or more arrangements, the ISR and/or the associated action (e.g., the measurement) as well as setting the duty cycle can be triggered by comparing a timer counting value TCNT to a plurality of comparison values. One example of doing so is shown in connection with FIGS. 5A and 5B. FIG. 5A shows a graph 500 of a timer counter 510 and a PWM signal 520 over time. Also shown is the period of the PWM signal 520, which can change over time. There can be a timer counting value TCNT which corresponds to the counting by the timer(s) 160. There can be an input compare register value ICR. The input compare register value ICR can set the frequency. The input compare register value ICR corresponds to a value at which point the timer counting value TCNT is reset. In this example, the comparison values against which the timer counting value TCNT is compared can include an output compare register value OCR and a measurement compare register value MCR. The output compare register value OCR and the measurement compare register value MCR can be set by a user or other entity. The output compare register value OCR can set the duty cycle. The measurement compare register value MCR can define when an ISR (with the accompanying action of measuring an electrical characteristic of the contracting member) is triggered. It should be noted that the output compare register value OCR, the measurement compare register value MCR, and the input compare register value ICR can be changed, if necessary or desired, over time, including for each period of the PWM signal.

In some arrangements, the measurement compare register value MCR can be set to a fraction or percentage of the output compare register value OCR. This way, if the output compare register value OCR is dynamically adjusted, the measurement compare register value MCR will continue to be less than the output compare register value OCR. While the output compare register value MCR can theoretically be 0% of the output compare register value OCR, such a relationship may not optimal because a small allowance of time should be made for current to rise in the contracting member (e.g., rise time).

FIG. 5B shows a logic table for triggering the ISR and the measurement. When the timer counting value TCNT is less than the output compare register value OCR, the PWM signal 520 is high. When the timer counting value TCNT equals the measurement compare register value MCR, the ISR and a measurement can be triggered. The measurement can be performed within the interruption. While the output compare register value OCR and the measurement compare register value MCR can be set to any suitable value, the measurement compare register value MCR can be less than or equal to the output compare register value OCR. If the measurement compare register value MCR is greater than the output compare register value OCR, then the measurement will be made when the PWM signal 520 is off, potentially leading to a non-meaningful measurement. Also, over the course of the various periods of the PWM signal 520, the measurement compare register value MCR and the output compare register value OCR can be separated by the same amount. Alternatively, over the course of the various periods of the PWM signal 520, the measurement compare register value MCR and the output compare register value OCR can be separated by different amounts.

With the logic table of FIG. 5B in mind, the graph 500 in FIG. 5A will now be described. The various periods of the PWM signal 520 will be reviewed in turn from left to right. In a first period 551, the duty cycle can be 0%, meaning the PWM signal 520 is low for the duration of the first period 551. The timer counter 510 (and the timer counting value TCNT) can start at zero or other baseline value. The timer counter 510 can increase from there. In the first period 551, the measurement compare register value MCR and the output compare register value OCR can be set to zero or the baseline counting value. Thus, as the timer(s) 160 begin counting, the timer counting value TCTN will exceed the output compare register value OCR, so the PWM signal 520 remains low). The timer counting value TCTN will exceed the measurement compare register value MCR, so a measurement is not made during the first period 551. The timer counter 510 can be compared to the input compare register value ICR. When the timer counter 510 exceeds the input compare register value ICR, the timer counter 510 can reset to zero or other baseline value.

The second period 552 can begin. In the second period 552, the output compare register value OCR can be set to maximum counter value (or to the input compare register value ICR value). Here, the output compare register value OCR can be equal to the input compare register value ICR. The measurement compare register value MCR can be set to about 75% of the output compare register value OCR. The timer(s) 160 can begin to count, and the timer counting value TCNT can increase. The PWM signal 520 can be high at all times during the second period 552 because the timer counting value is less than the output compare register OCR.

As the timer counting value TCNT increases, it will be less than the measurement compare register value MCR, the output compare register value OCR, and the input compare register value ICR. When the timer counting value TCNT equals the measurement compare register value MCR, the sensor(s) 140 can be activated to acquire data about one or more electrical characteristics of the contracting member(s). Since the timer counting value TCNT is still below the output compare register value OCR, the PWM signal 520 can remain on (high).

The timer counting value TCNT can continue to increase. When the timer counting value TCNT exceeds the input compare register value ICR, the timer counting value TCNT can be reset to zero. It will be appreciated that, during the second period 452, the duty cycle can be 100%, meaning that the PWM signal 420 is on for the entire period. In the second period 552, the duty cycle is 100% because the PWM signal 520 is on 100% of the time.

In the third period 553, the output compare register value OCR can be set to less than the input compare register value ICR. As an example, the output compare register value OCR can be set to about 75% of the maximum timer counting value (or about 75% of the input compare register value ICR), and the measurement compare register value MCR can be set to about 50% of the output compare register value OCR. At the beginning of the third period 553, the PWM signal 520 can remain high because timer counting value TCNT did not exceed the output compare register value OCR. When the timer counting value TCNT equals the measurement value MCR, a measurement of an electrical characteristic of the contracting member is made, such as by the sensor(s) 140. When the timer counting value TCNT exceeds the output compare register value OCR, the PWM signal 520 can be switched to low. It will be appreciated that the measurement is made while the PWM signal 420 is high and before it is switched to low.

The timer counting value TCNT can continue to increase. The PWM signal 520 can remain low because the timer counting value TCNT is greater than the output compare register value OCR. When the timer counting value TCNT reaches the input compare register value ICR, the timer counting value TCNT can be reset to zero. In the third period 553, the duty cycle is 75% because the PWM signal 520 is on 75% of the time and off 25% of the time.

In a fourth period 554, the output compare register value OCR can be set to less than the input compare register value ICR. As an example, the output compare register value OCR can be set to about 50% of the maximum counting value (or about 50% of the input compare register value ICR), and the measurement compare register value MCR can be set to a value that is less than the output compare register value OCR or to a value that is some percentage or fraction of the output compare register value OCR. The PWM signal 520 can switch to high (or on) because it is less than the output compare register value OCR. When the timer counting value TCNT equals the measurement compare register value MCR, a measurement of an electrical characteristic of the contracting member can be made, such as by the sensor(s) 140. It will be appreciated that the measurement is made while the PWM signal 420 is high and before it is switched to low. When the timer counting value TCNT exceeds the output compare register value OCR, the PWM signal 520 can be switched to low. The timer counting value TCNT can continue to increase. The PWM signal 520 can remain low because the timer counting value TCNT is greater than the output compare register value OCR. When the timer counting value TCNT exceeds the input compare register value ICR, the timer counting value TCNT can be reset to zero. In the fourth period 554, the duty cycle is 50% because the PWM signal 520 is on 50% of the time and off 50% of the time.

It will be appreciated that, by using two comparison values (the output compare register value OCR and the measurement compare register value MCR), any potential timing issues with measuring the electrical characteristic of the contracting member before the PWM signal is turned off can be avoided. The measurements can be stored in the data store(s) 130. The measurements can be provided as feedback to the control module(s) 180. Such feedback can be useful to monitoring and/or controlling the state of the contracting member(s).

The control module(s) 180 can be configured to monitor the electrical characteristic of the contracting member over time. Such information can be used for various purposes. For instance, the control module(s) 180 can be configured to control the state of the contracting member(s). Further, the control module(s) 180 can be configured to cycle the contracting member(s) between heated and cooled states.

To that end, the monitored values of the electrical characteristic can be monitored to detect when the measured values of the electrical characteristic substantially plateau. “Substantially plateau” means that the measured values do not change or do not substantially change over a period of time or over a number of measurements. “Do not substantially change” means within a predetermined percentage (e.g., within 10 percent or less, within 5 percent or less, within 4 percent or less, within 3 percent or less, within 2 percent or less, within 1 percent or less, or within about 0.5 percent or less, just to name a few possibilities).

In a cooling cycle, when it is detected that the measured electrical characteristic substantially plateaus, the control module(s) 180 can determine that the contracting member is sufficiently cooled. Thus, additional cooling of the contracting member will not result in any substantial change to the state of the contracting member. Moreover, further cooling of the contracting member can, in some instances, result in a greater heating input to be provided to the contracting member. Additionally, further cooling of the contracting member may be wasteful and inefficient.

In a heating cycle, when it is detected that the measured electrical characteristic substantially plateaus, the control module(s) 180 can determine that the contracting member is sufficiently heated. Thus, additional heating of the contracting member will not result in any substantial change to the state of the contracting member. Moreover, further heating of the contracting member can, in some instances, result in overstress and/or overheating, which can lead to a reduced life and/or effectiveness of the contracting member. Additionally, further heating of the contracting member may be wasteful and inefficient.

When a plateau is detected, the control module(s) 180 can take various actions. For instance, the control module(s) 180 can be configured to cycle the contracting member(s) between heated and cooled states. For instance, when the contracting member is determined to be sufficiently cooled during a cooling system, the control module(s) 180 can switch to a heating cycle of the contracting member(s). To that end, the control module(s) 180 can cause a duty cycle of the PWM signal to be increased such that a temperature of the contracting member increases. As a result, the cooling cycle transitions to a heating cycle.

As another example, when the contracting member is determined to be sufficiently heated during a heating cycle, the control module(s) 180 can switch to a cooling cycle of the contracting member(s). To that end, the control module(s) 180 can cause a duty cycle of the PWM signal to be decreased such that a temperature of the contracting member decreases. As a result, the heating cycle transitions to a cooling cycle.

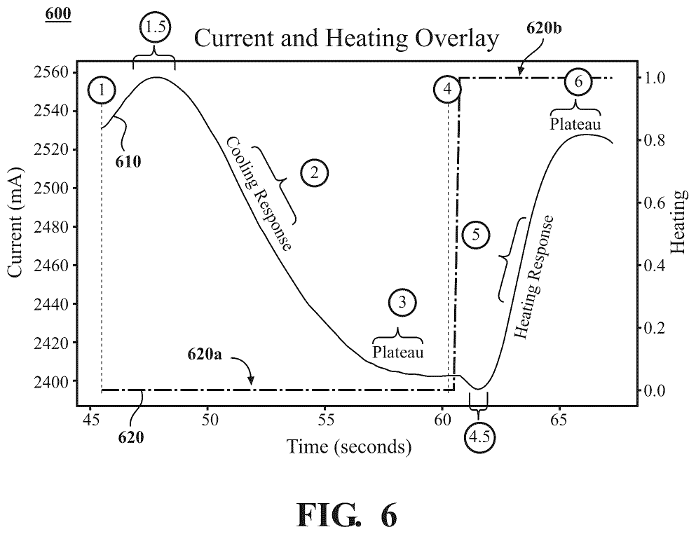

An example of such cycling is shown in FIG. 6, which shows an example of a graph 600 of current versus time is shown. The graph 600 includes a curve 610 representing current. The graph 600 also includes a representation of a heating variable 620. The heating variable 620 can be zero, off, or low at 620a, which means the contracting member is cooling, and a low duty cycle of power is being applied to the contracting member (but not enough to heat the contracting member). The heating variable 620 can shift to on one, on, or high at 620b, which means the contracting member is heating, and a high duty cycle of power is being applied to the contracting member.

Beginning on the left side of the figure at point 1, the contracting member is at the end of a heating cycle and at the beginning of a cooling cycle. The control module(s) 180 can switch from a heating cycle to a cooling cycle of the contracting member(s) by causing a duty cycle of the PWM signal to be decreased such that a temperature of the contracting member decreases.

Though the contracting member is in a cooling cycle, it will be appreciated that the curve 610 continues to rise until it peaks in what can considered to be a plateau region at point 1.5. Subsequently, the curve 610 can turn downwardly to the cooling response region at point 2.

The continued rise in current after point 1 will now be explained. At full activation, the contracting member has exhausted the shape memory effect. At point 1, the contracting member can be hot and may be heated past its actuation temperature. As a result, the material of the contracting member can be thermally expanded.

At the beginning of the cooling cycle at point 1, the contracting member begins to cool down. In the time before the plateau region at point 1.5, the contracting member has not cooled down below its activation temperature. As it cools down but before it drops below its actuation temperature, the contracting member thermally contracts, which reduces resistance and causes an increase in current.

As the contracting member cools past the activation temperature, the shape memory effect starts to become undone, causing expansion of the contracting member, thereby increasing resistance and reducing current. As a result, the curve 610 enters the plateau region at point 1.5. The curve 610 turns downwardly to the cooling response region at point 2 as the contracting member continues to cool.

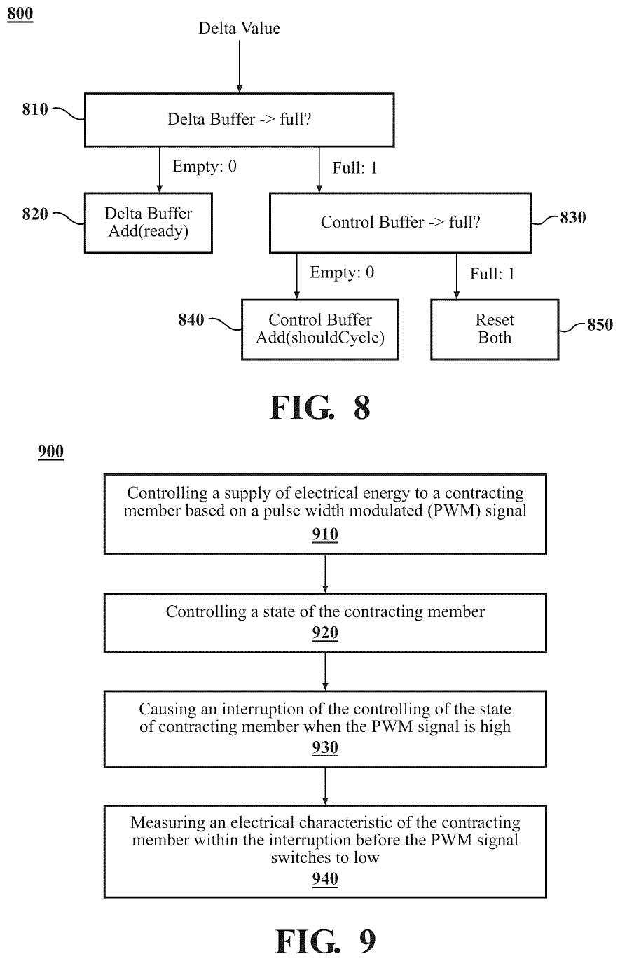

Thus, it will be appreciated that the current behaves nonlinearly as the contracting member switches between cycles. This nonlinearity is one reason a two-buffer system, as explained in greater detail below in connection with FIG. 8, can be beneficial. In a cooling cycle, a first buffer (delta buffer) can only full once a current decrease is detected (meaning the plateau region at point 1.5 has passed), and a second buffer (control buffer) is full once another plateau is achieved at point 3. The two-buffer system can ensure that the cycling of the contracting member is based on meaningful current measurements during the respective heating or cooling cycle.

Returning to the curve 610, the cooling response of the contracting member is shown at point 2. The measured current values will be falling in this region of the curve 610. The contracting member can be expanding and progressively losing its shape memory effect. When the contracting member fully loses its shape memory effect, it stops expanding and the measured current values can substantially plateau, resulting in a plateau region at point 3.

At point 4, the control module(s) 180 can determine that the contracting member is sufficiently cooled. the control module(s) 180 can switch to a heating cycle of the contracting member(s). To that end, the control module(s) 180 can cause a duty cycle of the PWM signal to be increased such that a temperature of the contracting member increases. As a result, the cooling cycle transitions to a heating cycle.

Though the contracting member is in a heating cycle, it will be appreciated that the curve 610 can continue to drop until it peaks in what can considered to be a plateau region at point 4.5. Subsequently, the curve 610 can turn upwardly to the heating response region at point 5.

The continued drop in current after point 4 will now be explained. At point 4, the contracting member can be cool and below its actuation temperature. The contracting member can begin to heat up in the heating cycle. In the time before the plateau region at point 4.5, the contracting member has not been heated above its activation temperature. Thus, as it heats up but before it reaches its actuation temperature, the contracting member can thermally expand, which increases resistance and causes a decrease in current.

As the contracting member heats past the activation temperature, the shape memory effect begins, causing contraction of the contracting member, thereby decreasing resistance and increasing current. As a result, the curve 610 enters the plateau region at point 4.5. The curve 610 turns upwardly as the contracting member continues to heat because the contracting member continues to contract, leading to a further decrease in resistance and increase in current.

Thus, the contracting member can enter the heating response of the curve 610, as is shown at point 5. Eventually, the measured current values can substantially plateau at point 6. The control module(s) 180 can detect this plateauing and can determine that the contracting member is sufficiently heated. The control module(s) 180 can switch to a cooling cycle of the contracting member(s). The process can be repeated as described above.

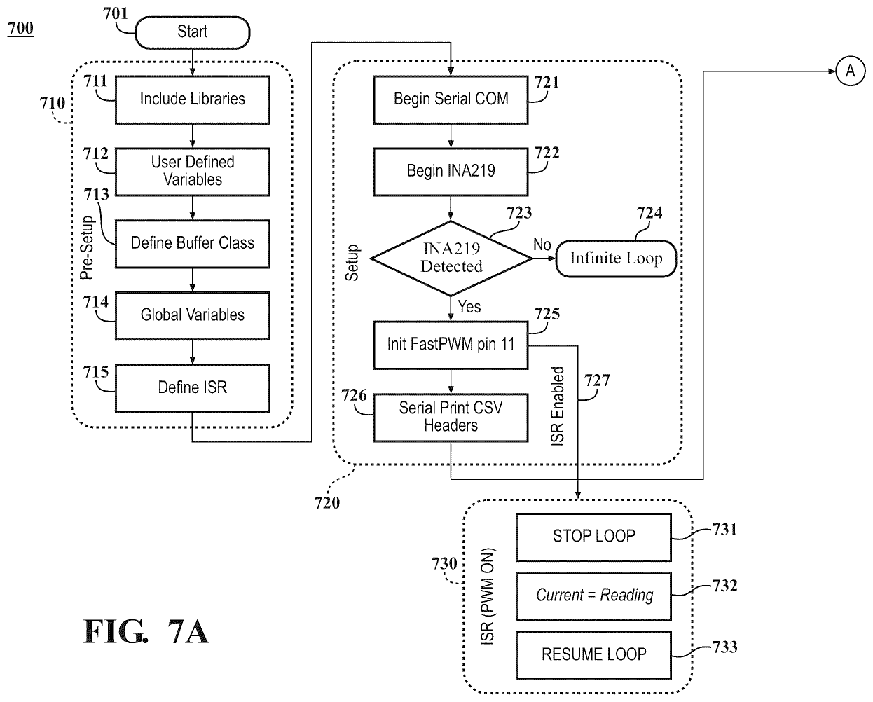

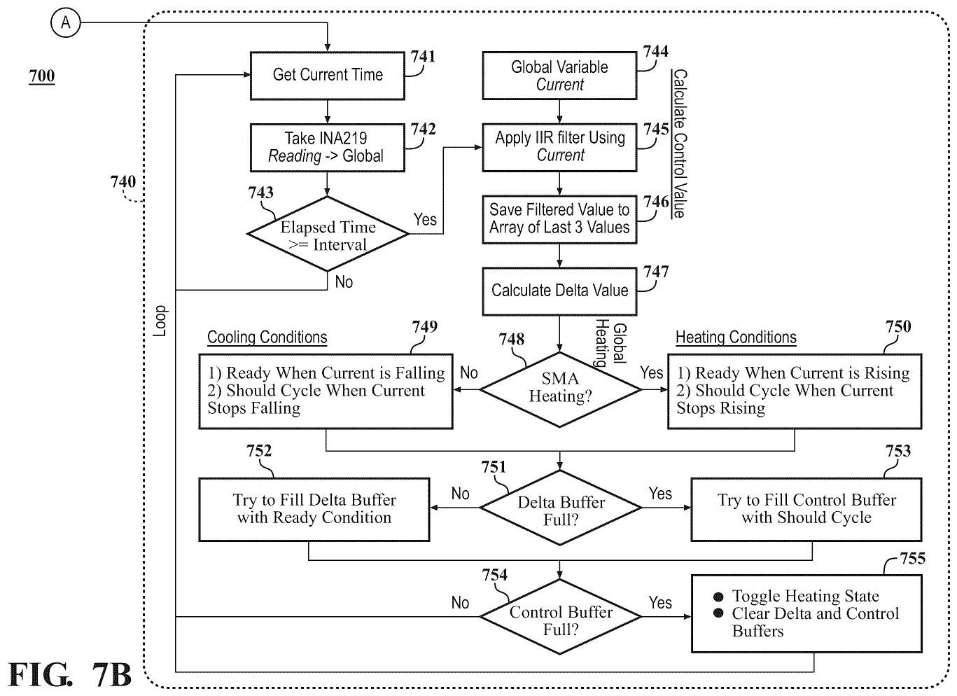

The control module(s) 180 can be configured to cycle a contracting member between cooling and heating cycles. Referring to FIGS. 7A-7B, an operational scheme 700 for cycling a contracting member between cooling and heating cycles is shown. The control module(s) 180 can be configured to run the operational scheme 700. FIG. 7A shows a first portion of the operational scheme, and FIG. 7B shows a second portion of the operational scheme.

Various possible phases and blocks of the operational scheme 700 will now be described. The operational scheme 700 described may be applicable to the arrangements described above, but it is understood that the operational scheme 700 can be carried out with other suitable systems and arrangements. Moreover, the operational scheme 700 may include other phases and/or blocks that are not shown here, and the operational scheme 700 is not limited to including every phase and/or block shown. The phases and/or blocks that are illustrated here as part of the operational scheme 700 are not limited to the particular chronological order. Indeed, some of the phases and/or blocks may be performed in a different order than what is shown and/or at least some of the phases and/or blocks shown can occur simultaneously.

In FIG. 7A, the operational scheme 700 can begin at block 701. The operational scheme 700 can continue to a pre-setup phase 710. In the pre-setup phase 710, libraries can be included at block 711, variables and classes can be set up at blocks 712, 713, 714. The ISR can be defined at block 715. After the pre-setup phase 710, the operation scheme 700 can continue to the setup phase 720.

In the setup phase 720, various actions can occur. For example, serial communications can begin at block 721, which can allow reports to be received on how the program is running. Further, the sensor (e.g., current sensor INA219) can be checked for at blocks 722, 723. The operational scheme 700 does not proceed (e.g., infinite loop 724) until the sensor is detected. When the sensor is detected, the PWM can be initialized at block 725. In this example, FastPWM can be used. When the PWM is initialized, the ISR can be enabled to start running at line 727. The ISR can be directly tied to the cycling of the PWM. The ISR and the PWM signal can be generated from a common source. Thus, the ISR can be timed precisely in relation to the PWM signal. At block 726, CSV headers can be printed, which can be used for data acquisition purposes.

After the setup phase 720, either the loop phase 740 is running or the ISR phase is running. Thus, the operational scheme 700 can continue to either the loop phase 740 (FIG. 7B) or the ISR phase 730 (FIG. 7A). When the ISR phase 730 is not running, the loop phase 740 is running. Conversely, then the loop phase 740 is not running, the ISR phase 730 is running. The ISR phase 730 has priority when it is actively running.

In the ISR phase 730, the loop phase 740 can be stopped at block 731. A current measurement of the contracting member can be made when the PWM is still on at block 732. After the current measurement is made, the loop phase 740 can be resumed at block 733. In some arrangements, the loop phase 740 can be resumed at the point in which it was interrupted by the ISR phase 730. In some arrangements, the loop phase 740 can be resumed at the beginning of the loop phase 740 or at any other point.

In the loop phase 740, the current time can be obtained at block 741. A current reading of the contracting member can be made at block 742. The current reading can be a reading taken in the past. At block 743, the operational scheme 700 can include checking to see if it is time to implement controls. The operational scheme 700 can do so by determining whether the elapsed time is greater than a control interval. If it is not, then the operational scheme 700 can return to block 741. If it is, then the operational scheme 700 can continue to calculate a control value by going to block 745. At block 745, a filter can be applied using current. Block 745 can assume that the global variable current has been uploaded by the ISR at block 744. The global variable current can be the current at block 732.

At block 746, the filtered value can be saved to an array of the last three values. At block 747, a delta value can be calculated. The delta value is based on the rate of change of current. From there, it can be determined whether the contracting member is heating at block 748.

If it is determined that the contracting member is not heating, then, at block 749, the cooling conditions can be established. The cooling conditions can include: (1) ready to cycle when current values are falling, and (2) should cycle when current values stop falling. With the cooling conditions established, the operational scheme 700 can continue to block 751.

If it is determined that the contracting member is heating, then, at block 750, the heating conditions can be established. The heating conditions can include: (1) ready to cycle when current values are rising, and (2) should cycle when current values stop rising. With the heating conditions established, the operational scheme 700 can continue to block 751.

At block 751, it can be determined whether the delta buffer is full. The delta buffer can correlate with “ready to cycle” in the heating conditions and the cooling conditions. Basically, the delta buffer is used to determine whether or not the operational scheme is ready to change state (e.g., cooling to heating, or heating to cooling).

If the delta buffer is not full, then the operational scheme 700 can proceed to block 752. At block 752, the system can try to fill the delta buffer with the ready condition. This can include continuing to block 754 and potentially block 741. The current values are compared to a buffer. If the condition (e.g., current is falling or current is rising) is true enough times over a window of time, then the delta buffer will become full at block 751. At this point, the operational scheme 700 is ready to cycle the state of the contracting member. In a cooling cycle, a full delta buffer would correspond to point 2 in FIG. 6. In a heating cycle, a full delta buffer would correspond to point 5 in FIG. 6.

If the delta buffer is full, then the operational scheme 700 can continue to block 753. At block 753, the system can try to fill the control buffer. The current values are compared to a buffer. If the condition (e.g., current is plateauing) is true enough times over a window of time, then the control buffer will become full at block 754. A full control buffer would correspond to point 3 in FIG. 6 during a cooling cycle. A full control buffer would correspond to point 6 in FIG. 6 during a heating cycle.

At this point, the operational scheme 700 should cycle or toggle the state of the contracting member at block 755. Such toggling would correspond to point 4 in FIG. 6 during a cooling cycle. Also, at block 755, the delta buffer and the control buffer can be cleared.

FIG. 8 is an example of a two buffer system 800 for cycling the contracting member between cooling and heating cycles. The two buffer system 800 relates to blocks 748 through block 755 of the operational scheme 700. The two buffer system 800 includes a first buffer (delta buffer), which corresponds to “ready to cycle” the state of the contracting member, and a second buffer (control buffer), which corresponds to “should cycle” the state of the contracting member. The first buffer and the second buffer can be in series such that the second buffer begins to fill only after the first buffer is full.

At block 810, the two buffer system 800 can evaluate whether the delta buffer is full. If the delta buffer is not full, then the two buffer system 800 can go to block 820 where the delta value is evaluated based on the “ready condition” and the delta buffer is added to with this evaluation. The two buffer system 800 can go back to the beginning. If the delta buffer is full, then the two buffer system 800 can continue to block 830. At block 830, the two buffer system 800 can evaluate whether the control buffer is full. If the control buffer is not full, then the two buffer system 800 can continue to block 840. At block 840, the delta buffer can be evaluated based on the “should cycle condition” and the control buffer can be added to with this evaluation. The two buffer system 800 can go back to the beginning.

If the control buffer is full, then the two buffer system 800 can continue to block 850, where the delta buffer and the control buffer are both reset. At this point, the heating/cooling cycle of the contracting member can be switched. Thus, if the contracting member was being heated, then it can be switched to being cooled. Alternatively, if the contracting member was being cooled, then it can be switched to being heated.

Now that the various potential systems, devices, elements and/or components of the system 100 have been described, various methods will now be described. Various possible steps of such methods will now be described. The methods described may be applicable to the arrangements described above, but it is understood that the methods can be carried out with other suitable systems and arrangements. Moreover, the methods may include other steps that are not shown here, and in fact, the methods are not limited to including every step shown. The blocks that are illustrated here as part of the methods are not limited to the particular chronological order. Indeed, some of the blocks may be performed in a different order than what is shown and/or at least some of the blocks shown can occur simultaneously.

Referring to FIG. 9, an example of a method 900 is shown. At block 910, a supply of electrical energy to a contracting member can be controlled based on a pulse width modulated (PWM) signal. The electrical energy can be from the energy source(s) 150. The control of the supply of electrical energy can be performed by the control module(s) 180 and/or the processor(s) 120. The PWM signal can be generated or caused to be generated by the timer(s) 160, the control module(s) 180 and/or the processor(s) 120. The method 900 can continue to block 920.

At block 920, a state of the contracting member can be controlled. Such controlling can be performed by the processor(s) 120 and/or the control module(s) 180. Such controlling can be performed by the processor(s) 120 executing or initiating executable operations. The controlling can include monitoring an electrical characteristic of the contracting member. The controlling can include changing an activation input to the contracting member, such as changing the duty cycle of the PWM signal. The method 900 can continue to block 930.

At block 930, an interruption to the controlling the state of the contracting member can be caused when the PWM signal is high. The interruption can be performed by the control module(s) 180, the timer(s) 160, and/or the processor(s) 120. In some arrangements, the interruption can be performed using an interrupt service routine. The interrupt service routing can interrupt a main code (e.g., executable operations) being executed by the processor(s) 120. The method 900 can continue to block 940.

At block 940, an electrical characteristic of the contracting member can be measured or caused to be measured within the interruption before the PWM signal switches to low. The measuring of the PWM signal can be performed by the sensor(s) 140, such as a multimeter. The sensor(s) 140 can be activated or caused to measure the electrical characteristic by the control module(s) 180 and/or the processor(s) 120.

The method 900 can end. Alternatively, the method 900 can return to block 910 or to some other block. The method 900 can be repeated at any suitable point, such as at a suitable time or upon the occurrence of any suitable event or condition.

In some arrangements, the method 900 can include additional blocks not shown in FIG. 9. For instance, the method 900 can include monitoring the electrical characteristic of the contracting member over time by repeating block 910, 920, 930 over time. The method 900 can include detecting when the electrical characteristic substantially plateaus. In such case, it can be determined that the contracting member is sufficiently cooled or sufficiently heated, depending on whether the contracting member is in a cooling or heating cycle. The method 900 can include cycling the contracting member between heating and cooling cycles. The method 900 can do so by causing a duty cycle of the PWM signal to be increased or decreased. Such causing can be performed by the control module(s) 180 and/or the processor(s) 120.

As noted above, arrangements described herein can be used in connection with the cycling of a contracting member. Such cycling of the contracting member can be useful in various applications, such as providing a massaging or haptic effect. However, it will be appreciated that arrangements described herein are not limited to being used in connection with the cycling of the contracting member.

Arrangements described herein can be used in any application in which shape memory material-based actuators are used. For instance, arrangements described herein can be used in connection with seat actuators or other actuators in a vehicle. “Vehicle” means any form of transport, including motorized or powered transport. In one or more implementations, the vehicle can be an automobile. In some implementations, the vehicle may be a watercraft, an aircraft, spacecraft, or any other form of transport. However, it will be appreciated that arrangements described herein are not limited to vehicular applications. For instance, arrangements described herein can be used in connection with an office chair, a chair, a massage chair, a gaming chair, a recliner, or any other seat structure, now known or later developed. Of course, arrangements are not limited to seat-related applications.

It will be appreciated that arrangements described herein can provide numerous benefits, including one or more of the benefits mentioned herein. For example, arrangements described herein can enable determining when a maximum actuated state of a contracting member is achieved. Arrangements described herein can enable determining when a sufficiently cooled or relaxed state of a contracting member is achieved. Arrangements described herein can allow for clear/instantaneous current measurements to be made. Arrangements described herein can protect a contracting member from overheating and/or overstressing. Arrangements described herein can help to maximize the useful life of a contracting member. Arrangements described herein can facilitate improved performance of a contracting member-based actuator.

The flowcharts and block diagrams in the figures illustrate the architecture, functionality, and operation of possible implementations of systems, methods and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or other apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk drive (HDD), a solid state drive (SSD), a random access memory (RAM), a read-only memory (ROM), an erasable programmable read-only memory (EPROM or Flash memory), an optical fiber, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain or store a program for use by or in connection with an instruction execution system, apparatus, or device.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “or” is intended to mean an inclusive “or” rather than an exclusive “or.” The phrase “at least one of . . . and . . . ” as used herein refers to and encompasses any and all possible combinations of one or more of the associated listed items. As an example, the phrase “at least one of A, B and C” includes A only, B only, C only, or any combination thereof (e.g., AB, AC, BC or ABC). As used herein, the term “substantially” or “about” includes exactly the term it modifies and slight variations therefrom. Thus, the term “substantially parallel” means exactly parallel and slight variations therefrom. “Slight variations therefrom” can include within 15 degrees/percent/units or less, within 14 degrees/percent/units or less, within 13 degrees/percent/units or less, within 12 degrees/percent/units or less, within 11 degrees/percent/units or less, within 10 degrees/percent/units or less, within 9 degrees/percent/units or less, within 8 degrees/percent/units or less, within 7 degrees/percent/units or less, within 6 degrees/percent/units or less, within 5 degrees/percent/units or less, within 4 degrees/percent/units or less, within 3 degrees/percent/units or less, within 2 degrees/percent/units or less, or within 1 degree/percent/unit or less. In some instances, “substantially” can include being within normal manufacturing tolerances.

Aspects herein can be embodied in other forms without departing from the spirit or essential attributes thereof. Accordingly, reference should be made to the following claims, rather than to the foregoing specification, as indicating the scope hereof.

What is claimed is:

1. A method comprising:
controlling a supply of energy to a contracting member based on a pulse width modulated (PWM) signal;
controlling a state of the contracting member;
causing an interruption of the controlling the state of the contracting member when the PWM signal is high; and
measuring an electrical characteristic of the contracting member within the interruption before the PWM signal switches to low.

2. The method of claim 1, wherein causing the interruption of the controlling the state of the contracting member when the PWM signal is high is performed using an interrupt service routine.

3. The method of claim 2, wherein the controlling the state of the contracting member is performed by one or more processors executing executable operations, whereby the interrupt service routine interrupts the executable operations.

4. The method of claim 2, wherein the interrupt service routine and the PWM signal are generated using a timer, whereby the interrupt service routine and the PWM are based on a common source.

5. The method of claim 1, wherein the electrical characteristic is current.

6. The method of claim 1, wherein the contracting member is a part of an actuator.

7. The method of claim 1, wherein the contracting member is a shape memory material member.

8. The method of claim 7, wherein the shape memory material member is a shape memory alloy wire.

9. The method of claim 1, wherein, in a cooling cycle, the PWM signal is at a duty cycle that does not cause a temperature of the contracting member to increase.

10. The method of claim 9, further including:
monitoring the electrical characteristic of the contracting member over time by repeating the causing and measuring; and
detecting when the electrical characteristic substantially plateaus, whereby the contracting member is determined to be sufficiently cooled.

11. The method of claim 10, further including:
when the contracting member is determined to be sufficiently cooled, causing a duty cycle of the PWM signal to be increased such that a temperature of the contracting member increases, whereby the cooling cycle transitions to a heating cycle.

12. The method of claim 1, wherein, in a heating cycle, the PWM signal is at a duty cycle that causes a temperature of the contracting member to increase, whereby the contracting member contracts.

13. The method of claim 12, further including:
monitoring the electrical characteristic of the contracting member over time by repeating the causing, and measuring; and
detecting when the electrical characteristic substantially plateaus, whereby the contracting member is determined to be sufficiently heated.

14. The method of claim 10, further including:
when the contracting member is sufficiently heated, causing a duty cycle of the PWM signal to be decreased such that a temperature of the contracting member decreases, whereby the heating cycle transitions to a cooling cycle.

15. The method of claim 1, wherein the measured electrical characteristic of the contracting member is used in the controlling of the state of the contracting member.

16. The method of claim 1, further including:
monitoring the electrical characteristic of the contracting member over time by repeating the causing and measuring; and
switching the contracting member from one of a heating cycle and a cooling cycle to the other one of the heating cycle and the cooling cycle based on a two buffer system using the measured electrical characteristics of the of the contracting member.

17. The method of claim 16, wherein the two buffer system includes a first buffer and a second buffer in series, whereby the second buffer begins to fill after the first buffer is full.

18. The method of claim 17, wherein the first buffer corresponds to a condition in which the contracting member is ready to cycle, and wherein the second buffer corresponds to a condition in which the contracting member should be cycled.

19. A system comprising:
a contracting member;
an energy source configured to supply energy; and
one or more processors operatively connected to the contracting member and to the energy source, the one or more processors being programmed to:
control a supply of energy from the energy source to the contracting member based on a pulse width modulated (PWM) signal;
control a state of the contracting member;
cause an interruption of the controlling the state of the contracting member when the PWM signal is high; and
measuring an electrical characteristic of the contracting member within the interruption before the PWM signal switches to low.

20. The system of claim 19, further including an actuator, wherein the contracting member is a part of the actuator.

21. The system of claim 19, further including a switching device, wherein the one or more processors are operatively connected to the switching device to control the supply of electrical energy from the energy source to the contracting member.

22. The system of claim 19, wherein causing the interruption of the controlling the state of the contracting member when the PWM signal is high is performed using an interrupt service routine.

23. The system of claim 22, wherein the controlling the state of the contracting member is performed by the one or more processors executing executable operations, whereby the interrupt service routine interrupts the executable operations.

24. The system of claim 19, wherein the measured electrical characteristic of the contracting member is used in the controlling of the state of the contracting member.

25. The system of claim 19, wherein the electrical characteristic is current.

26. The system of claim 19, wherein the contracting member is a shape memory material member.

27. The system of claim 26, wherein the shape memory material member is a shape memory alloy wire.

28. The system of claim 19, wherein, in a cooling cycle, the PWM signal is at a duty cycle that does not cause a temperature of the contracting member to increase.

29. The system of claim 28, wherein the one or more processors are further programmed to:
monitor the electrical characteristic of the contracting member over time by repeating the causing and measuring; and
detect when the electrical characteristic substantially plateaus, whereby the contracting member is determined to be sufficiently cooled.

30. The system of claim 29, wherein the one or more processors are further programmed to:
when the contracting member is determined to be sufficiently cooled, cause a duty cycle of the PWM signal to be increased such that a temperature of the contracting member increases, whereby the cooling cycle transitions to a heating cycle.

31. The system of claim 19, wherein, in a heating cycle, the PWM signal is at a duty cycle that causes a temperature of the contracting member to increase, whereby the contracting member contracts.

32. The system of claim 31, wherein the one or more processors are further programmed to:
monitor the electrical characteristic of the contracting member over time by repeating the causing and measuring; and
detect when the electrical characteristic substantially plateaus, whereby the contracting member is determined to be sufficiently heated.

33. The system of claim 32, wherein the one or more processors are further programmed to:
when the contracting member is sufficiently heated, cause a duty cycle of the PWM signal to be decreased such that a temperature of the contracting member decreases, whereby the heating cycle transitions to a cooling cycle.

34. The system of claim 19, wherein the one or more processors are further programmed to:
monitor the electrical characteristic of the contracting member over time by repeating the causing and measuring; and
switching the contracting member from one of a heating cycle and a cooling cycle to the other one of the heating cycle and the cooling cycle based on a two buffer system using the measured electrical characteristics of the of the contracting member.

35. The system of claim 34, wherein the two buffer system includes a first buffer and a second buffer in series, whereby the second buffer begins to fill after the first buffer is full.

36. The system of claim 35, wherein the first buffer corresponds to a condition in which the contracting member is ready to cycle, and wherein the second buffer corresponds to a condition in which the contracting member should be cycled.
